(19) United States
(12) Patent Application Publication
(10) Pub. No.: US 2004/0253837 A1
(43) Pub. Date: Dec. 16, 2004

(54) Method for forming a dielectric layer of a semiconductor

(76) Inventor: Yu-Hao Yang, Hsin-Chu (TW)

Correspondence Address: BIRCH STEWART KOLASCH & BIRCH, PO BOX 747, FALLS CHURCH, VA, 22040-0747, US

(21) Appl. No.: 10/457,520

(22) Filed: Jun. 10, 2003

(51) Int. Cl. H01L 21/44; H01L 21/31; H01L 21/469

(52) U.S. Cl. 438/782; 438/778

(57) ABSTRACT

A method for forming a dielectric layer of a semiconductor is described. At first, providing a substrate with a metal-conductive layer having been formed thereon. Next covering the substrate with a membrane having a plurality of micro-holes. Afterward spraying a fluid dielectric on the membrane having a plurality of micro-holes. After waiting a period of time for the gaps among the metal conductors being filled with the fluid dielectric, removing the membrane having a plurality of micro-holes from the substrate. Further baking the substrate to cure the fluid dielectric inside metal-conductive layer. The thickness of the dielectric after curing is approximately equal to the thickness of the metal-conductive layer. At last forming a cap dielectric layer on the substrate.

### BACKGROUND OF THE INVENTION

1. Field of the Invention

The present invention relates to a manufacturing process of semiconductors, especially relates to the manufacturing process of dielectric layers between metal conductors.

2. Description of the Prior Art

After the fabrication of the active device of a MOS(metal-oxide semiconductor) device is accomplished, the following work is to proceed with the fabrication of the multilevel interconnects above the MOS device. As the process technology progresses and scales of MOS devices get more and more smaller, gaps between metal conductors also become more and more narrower. Accordingly, gaps of high aspect ratio between metal conductors are formed. The gaps of high aspect ratio will let the deposition of dielectric layers become incomplete and form voids in the dielectric layers. These voids in the dielectric layers will damage electric properties of MOS devices and lead to scraped wafers.

In order to solve the problem of the incomplete deposition of dielectric layers, a HDPCVD(high density plasma chemical vapor deposition) process is proposed to deposit dielectric layers between metal conductors in U.S. Pat. No. 6,239,018 and U.S. Pat. No. 6,218,284. The detailed description of a HDPCVD process is also contained in U.S. Pat. No. 6,117,345. The main reason a HDPCVD process can solve the problem of the incomplete deposition of dielectric layers is that a HDPCVD process is capable of proceeding with both chemical vapor deposition process and anisotropic etching process. The HDPCVD process is as shown from FIG. 1A to FIG. 1D, at fist providing a substrate 10 with active devices of semiconductors having been formed inside and with a metal conductor layer 12 having been formed thereon. Further forming a first dielectric layer 14 on the metal conductor layer 12 by a HPDCVD process. Herein the figure of the dielectric layer 14 above the conductor layer 12 is saw-toothed as shown in FIG. 1B. Next forming a second dielectric layer 16 on the first dielectric layer. Afterwards planarizing the second dielectric layer 16(such as Chemical Mechanical Polish abbr. CMP process) and the whole structure of the wafer will be as shown in FIG. 1D.

Because the thickness in some portion of the first dielectric layer 14 formed by a HDPCVD process is high and in the other portion of the first dielectric layer 14 is low, besides some portion of the metal conductor layer 12 is dense and the other portion of the metal conductor layer 14 is loose, the figure of the second dielectric layer 16 covered on the first dielectric layer 14 will also rise and fall. Accordingly in order to facilitate the fabrication of the following metal layer, a planarization process(such as CMP process) has to be added to planarize the second dielectric layer 16, causing that the process steps are added and the time for manufacturing semiconductors is increased. As a result there is a need for getting a smooth surface of a dielectric layer between metal conductors without proceeding with a planarization process.

As the aspect ratio of the gaps between metal conductors inside a semiconductor gets higher and higher, when proceeding with a HDPCVD process to form a dielectric layer between metal conductors, the etching speed to the depositing speed ratio has to be increased to form a void-free dielectric layer, always causing that the manufacturing time is increased and even that a void-free dielectric layer still can not be formed. Accordingly there is a need for forming a void-free dielectric layer between metal conductors without increasing the manufacturing time.

### SUMMARY OF THE INVENTION

One main purpose of the present invention is to provide a method for forming a smooth dielectric layer between metal conductors in a semiconductor and to subtract the planarization process in the prior art to save the manufacturing time and cost.

The other purpose of the present invention is to provide a method for forming a void-free dielectric layer between metal conductors in a semiconductor in place of the time-consuming HDPCVD process in the prior art.

The present invention uses a membrane having a plurality of micro-holes to tightly cover on a substrate with a metal conductor layer having been formed thereon. Next spraying a fluid dielectric on the substrate. After waiting a period of time for the gaps among the metal conductors being filled with the fluid dielectric, removing the membrane having a plurality of micro-holes from the substrate. Further baking the substrate to evaporate the solvent in the fluid dielectric to cure the fluid dielectric inside metal-conductive layer to form a first dielectric layer between metal conductors. And then forming a second dielectric layer on the first dielectric layer by a chemical vapor deposition process on the substrate to complete the fabrication of the dielectric layer between metal conductors.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A-1D illustrate the steps of a HDPCVD process for forming a dielectric layer between metal conductors in a semiconductor of the prior art;

FIG. 2A-2E illustrate the steps of using a membrane having a plurality of micro-holes to form a dielectric layer between metal conductors in a semiconductor of the present invention;

FIG. 3A shows a schematic chart of the growing direction of a dielectric layer between metal conductors, the dielectric layer which is formed by chemical vapor deposition; and

FIG. 3B shows a schematic chart of the growing direction of a dielectric layer between metal conductors, the dielectric which is formed with a membrane having a plurality of micro-holes penetrated by fluid dielectric of the present invention.

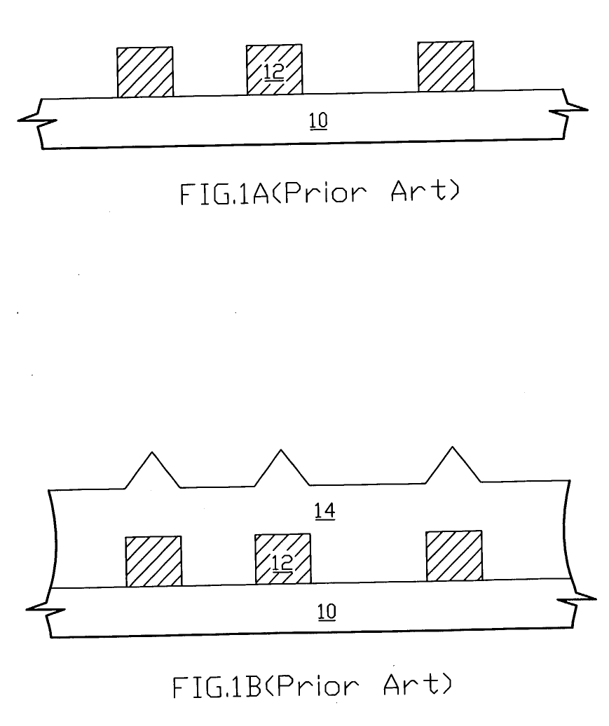

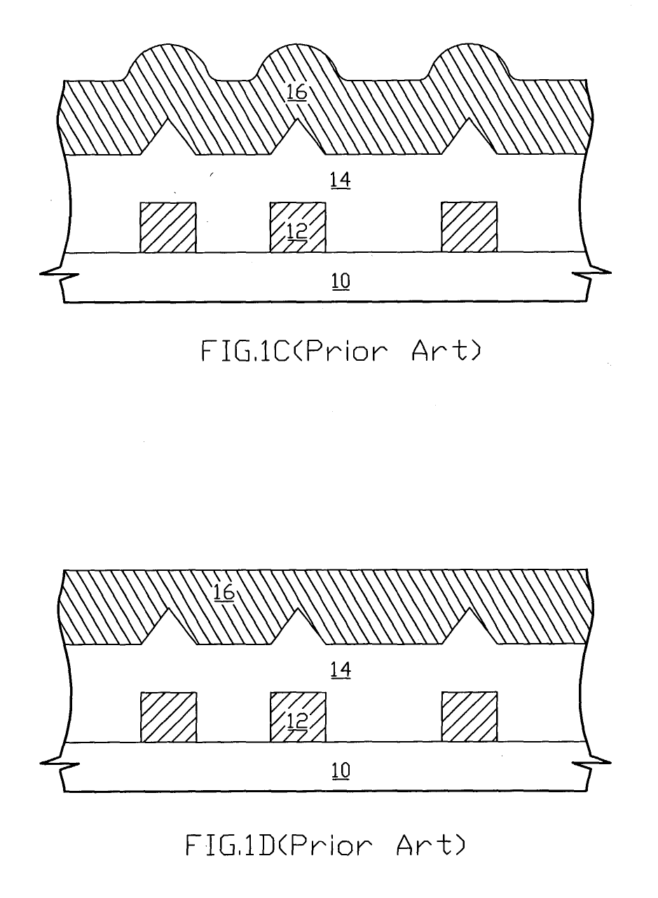

### DESCRIPTION OF THE PREFERRED EMBODIMENT

Some embodiments of the invention will be described exquisitely as below. Besides, the invention can also be practiced extensively in other embodiments. That is to say, the scope of the invention should not be restricted by the proposed embodiments. The scope of the invention should be based on the claims proposed later.

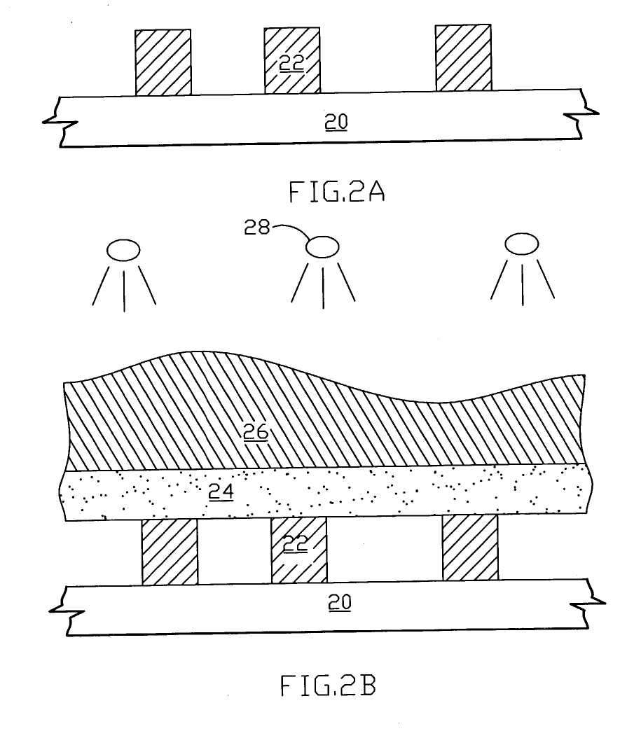

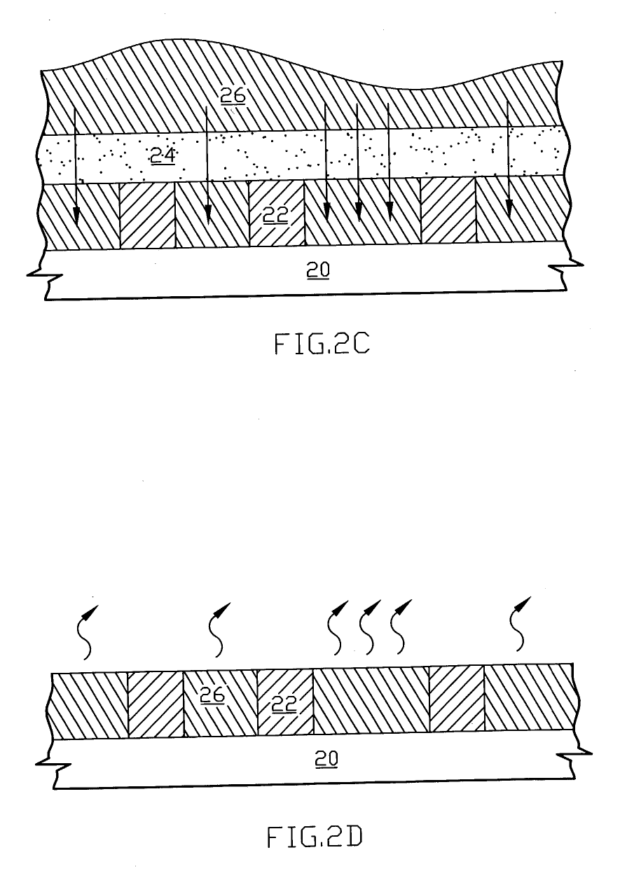

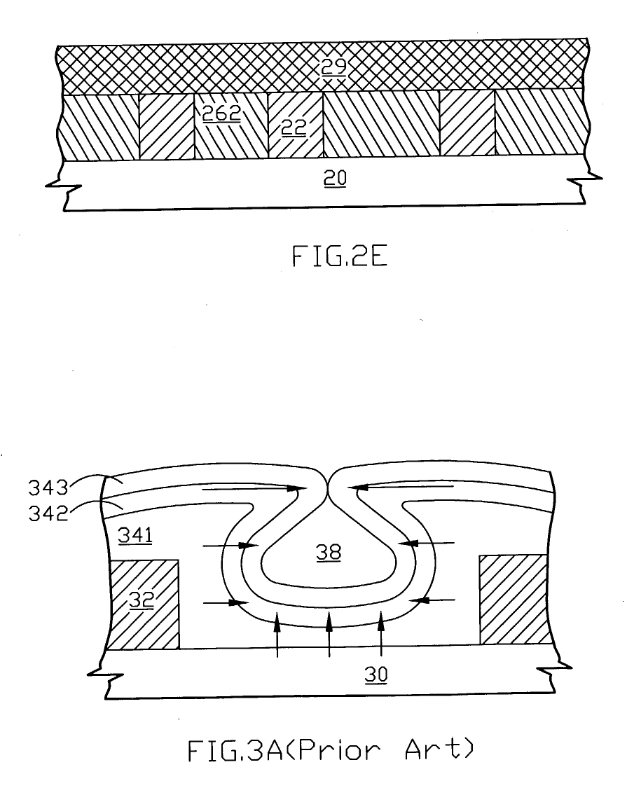

One preferred embodiment of the present invention is described as follows. As shown in FIG. 2A, a metal conductor 22 layer has been formed on a substrate 20. Herein the substrate 20 includes the active device (not shown in the figure) of the semiconductor to be manufactured. The following step is to proceed with the fabrication of the dielectric layer between the metal conductors to isolate the metal conductors 22 from each other and to isolate the metal conductor 22 layer from the next metal conductor layer (not shown in the figure).

Before the dielectric layer between metal conductors 22 is manufactured in the process chamber, as shown in FIG. 2B, the substrate 20 is tightly covered with a membrane having a plurality of micro-holes 24 or the substrate 20 tightly neighbors below a membrane having a plurality of micro-holes 24. Because there is a little difference of thickness among a plurality of metal conductors 22 after fabrication, the membrane having a plurality of micro-holes 24 is a soft material capable of closely adhering to the top surfaces of the metal conductors 22 on the substrate 20. The membrane having a plurality of micro-holes 24 is a filter which does not react with the chemical materials used in the manufacturing process of the dielectric layer. In the embodiment the membrane having a plurality of micro-holes is chosen from the group consisting of a nonwoven filter, a ceramic filter, and a stainless filter.

Next spraying fluid dielectric 26 on the membrane having a plurality of micro-holes 24 by a plurality of nozzles 28. Herein the fluid dielectric 26 consists of a solvent and a dielectric material soluble in the solvent. Depending upon different process needs, the fluid dielectric 26 could be silicate, siloxane, HSQ(hydrogenated silsesqioxane), aromatic polyether, co-polymar of divinylsiloxane and bis-Benzocyclobutene, aerogel, or xerogel.

As shown in FIG. 2C, after the fluid dielectric 26 sprayed by a plurality of nozzles 28 penetrates through the membrane having a plurality of micro-holes 24, the fluid dielectric 26 will fill into the gaps between metal conductors 22. Herein the diameter of the micro-holes of the membrane having a plurality of micro-holes is chosen to meet the process need. After a period of time and the fluid dielectric 22 fills whole gaps between metal conductors 22, removing the membrane having a plurality of micro-holes 24 from the substrate 20 or removing the substrate 20 from the membrane having a plurality of micro-holes 24. Next as shown in FIG. 2D, baking the substrate 20 to evaporate the solvent in the fluid dielectric 26 between metal conductors 22, and then the fluid dielectric 26 between metal conductors 22 is cured to form a first dielectric layer 262 as shown in FIG. 2E. Afterwards, forming a second dielectric layer 29 by a chemical vapor deposition process on the first dielectric layer 262 to complete the fabrication of the dielectric layer between metal conductors of a semiconductor. Herein because the thickness of the first dielectric layer 262 is similar to the thickness of the metal conductors, after the deposition of the second dielectric layer 29, the surface of the second dielectric layer 29 will be a smooth surface. And then it is not necessary to proceed with a CMP process as done in the prior art to planarize the second dielectric layer 29.

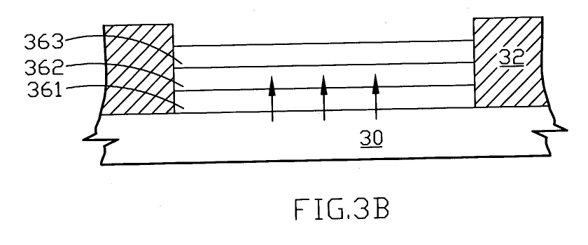

Now refering to FIG. 3A and FIG. 3B, the main difference of the dielectric layer formed between metal conductors between the present invention and the prior art lies in the growing direction when the dielectric layer is formed. As shown in FIG. 3A, the growing direction of the dielectric layer formed by chemical vapor deposition between metal conductors 32 on the substrate 30 in the prior art from the first dielectric layer 341 to the second dielectric layer 342 and finally to the third dielectric layer 343 includes vertical and lateral direction. Because the lateral growing speed of the dielectric layer is faster than the vertical growing speed of the dielectric layer or the gap width is smaller than the gap height, a void 38 will always be formed inside the dielectric layer between metal conductors 32. In the present invention, as shown in FIG. 3B, the growing direction of the dielectric layer between metal conductors 32 on the substrate 30 from the first dielectric layer 361 to the second dielectric layer 362 and finally to the third dielectric layer 363 includes only vertical direction. Therefore a void 38 will not be formed inside the dielectric layer between metal conductors 32 after completing the fill of the dielectric layer and then an electrically stable dielectric layer is formed.

What is said above is only a preferred embodiment of the invention, which is not to be used to limit the claims of the invention; any change of equal effect or modifications that do not depart from the essence displayed by the invention should be limited in what is claimed in the following. For example, the aforementioned metal conductor layer 22 in the embodiment could be the first level metal layer of the semiconductor to be manufactured and the substrate 20 represents the silicon substrate which contains the active devices of the semiconductor. Besides, the aforementioned metal conductor layer 22 in the embodiment could also be other level metal layer of the semiconductor to be manufactured and the substrate 20 represents a dielectric layer between adjacent metal layers of the semiconductor.

What is claimed is:

1. A method for forming a dielectric layer of a semiconductor, comprising:
providing a substrate, wherein a conductive layer has been patterned on said substrate;
covering said patterned conductive layer with a membrane having a plurality of micro-holes;
spraying fluid dielectric on said membrane having a plurality of micro-holes;
waiting for a period time and removing said membrane having a plurality of micro-holes from said substrate after said fluid dielectric completely fills gaps in said conductive layer; and
baking said substrate to cure said fluid dielectric in said conductive layer.

2. The method for forming a dielectric layer of a semiconductor according to claim 1, further comprising forming a cap dielectric layer on said patterned conductive layer filled with the cured dielectric.

3. The method for forming a dielectric layer of a semiconductor according to claim 2, wherein said cap dielectric layer is formed by a chemical vapor deposition process.

4. The method for forming a dielectric layer of a semiconductor according to claim 1, wherein said membrane of a plurality of micro-holes is chosen from the group consisting of a nonwoven filter, a ceramic filter, and a stainless filter.

5. The method for forming a dielectric layer of a semiconductor according to claim 1, wherein said fluid dielectric is chosen from the group consisting of silicate, siloxane, HSQ(hydrogenated silsesqioxane), aromatic polyether, co-polymar of divinylsiloxane and bis-Benzocyclobutene, aerogel, and xerogel.

6. A method for forming a dielectric layer of a semiconductor, comprising:
providing a substrate, wherein a metal conductor layer has been formed on said substrate;
attaching said substrate to a membrane having a plurality of micro-holes;
spraying fluid dielectric on said membrane having a plurality of micro-holes;
waiting for a period time and removing said substrate from said membrane having a plurality of micro-holes after said fluid dielectric completely fills gaps in said metal conductor layer;
baking said substrate to cure said fluid dielectric in said metal conductor layer, wherein a thickness of said fluid dielectric after curing is similar to a thickness of said metal conductor layer; and
forming a cap dielectric layer on said substrate.

7. The method for forming a dielectric layer of a semiconductor according to claim 6, wherein said membrane of a plurality of micro-holes is chosen from the group consisting of a nonwoven filter, a ceramic filter, and a stainless filter.

8. The method for forming a dielectric layer of a semiconductor according to claim 6, wherein said fluid dielectric is chosen from the group consisting of silicate, siloxane, HSQ(hydrogenated silsesqioxane), aromatic polyether, co-polymar of divinylsiloxane and bis-Benzocyclobutene, aerogel, and xerogel.

9. The method for forming a dielectric layer of a semiconductor according to claim 6, wherein said cap dielectric layer is formed by a chemical vapor deposition process.
